(19) United States
(12) Patent Application Publication
(10) Pub. No.: US 2015/0083376 A1
(43) Pub. Date: Mar. 26, 2015

(54) COLD-FORMED SACHET MODIFIED ATMOSPHERE PACKAGING

(71) Applicant: GOOGLE INC., MOUNTAIN VIEW, CA (US)

(72) Inventor: Hamburgen Hamburgen, Palo Alto, CA (US)

(73) Assignee: GOOGLE INC., MOUNTAIN VIEW, CA (US)

(21) Appl. No.: 14/145,835

(22) Filed: Dec. 31, 2013

Related U.S. Application Data
(60) Provisional application No. 61/882,368, filed on Sep. 25, 2013.

(51) Int. Cl. H05K 7/20; B65B 9/087

(52) U.S. Cl. CPC H05K 7/20; B65B 9/087
USPC 165/135; 53/455

(57) ABSTRACT

A pouch containing a gas is formed by drawing a first elongated sheet of gas-impermeable material from a supply of the material in a drawing direction. The sheet has a transverse profile perpendicular to the drawing direction that includes a channel. A second sheet of material is drawn, such that a first portion of the first sheet and a first portion of the second sheet are substantially parallel to each other. The gas is injected between the first portion of the first sheet and the first portion of the second sheet. First and second lengths of the first and second sheets are sealed to each other, where the first and second lengths are substantially parallel to the drawing direction, to form first and second side edges of the pouch. Third and fourth lengths of the sheets are sealed to each other to form first and second end edges of the pouch.

### CROSS REFERENCE TO RELATED APPLICATIONS

This application is a Continuation of, and claims priority to, U.S. Provisional Patent Application No. 61/882,368, filed on Sep. 25, 2013, entitled “COLD-FORMED SACHET MODIFIED ATOMSPHERIC PACKAGING, the disclosure of which is incorporated by reference herein in its entirety.

### TECHNICAL FIELD

This disclosure relates to forming gas-filled packages and, in particular, to cold-formed sachet modified atmosphere packaging.

### BACKGROUND

In laptop computers and other electronics, hot components near the inner case wall often create external hotspots that can be uncomfortable or dangerous to the user. In other words, when an electrical component is being used, the electrical component may generate heat. This electrical component may transfer heat to the enclosure of the device, thereby to the user, which essentially creates a hotspot on the enclosure that may be uncomfortable or dangerous to the user especially in the case of a metal enclosure.

The International Electrotechnical Commission (IEC) provides a set of standards for electrical devices, which includes a maximum temperature limit for areas on the device itself. Typically, most electronic manufacturers adhere to this requirement by limiting the temperature below the maximum temperature provided by the IEC. One particular example of an IEC standard indicates that if the device has a surface (e.g., easily conducts heat) the metal surface has to be held at a lower temperature than a plastic surface. For example, with heated metal surfaces, the heat can quickly be transferred to the user touching the hot metal surface; therefore, the metal surface can feel relatively hot even at a relatively low temperature. However, metal surfaces for electrical devices are typically used because they can quickly transfer heat from the hot electrical component, thereby keeping the hot electrical component cooler. As such, in some situations, a hotspot on the metal enclosure may occur over the hot electrical component. Further, in the event that an electrical component (e.g., CPU) is processing video graphics, the metal case enclosure may be very hot in the area of the CPU. Plastic surfaces also can develop hotspots in the same or similar ways.

Generally, in order to avoid a hot spot on the metal case enclosure, a system designer may create an air gap between the hot component and the enclosure. The size of the air gap may be relatively proportional to the usefulness of the insulation, e.g., the larger the air gap between the hot component and the enclosure, the better the insulation. As such, the size of the air gap may be considered a critical item for determining the overall thickness of the device. With that said, in the area of consumer electronics, thinner electronic devices may be more marketable. In contrast, bulkier consumer electronics may have a perception of being lower quality. Therefore, there may be an incentive to design an electronic device as thin as possible, which greatly affects the air gap, thereby affecting the heat transferred to the user.

### SUMMARY

The details of one or more implementations are set forth in the accompanying drawings and the description below. Other features will be apparent from the description and drawings, and from the claims.

In a first general aspect, a method of forming a pouch containing a gas includes drawing a first elongated sheet of gas-impermeable material from a supply of the material in a drawing direction, where the sheet of material has a transverse profile perpendicular to the drawing direction that includes a channel. A second elongated sheet of material is drawn, such that a first portion of the first sheet and a first portion of the second sheet are substantially parallel to each other. The gas is injected between the first portion of the first sheet and the first portion of the second sheet, and the gas is injected between side edges of the first portions of the first and second sheets. First and second lengths of the first and second sheets are sealed to each other, where the first and second lengths are substantially parallel to the drawing direction, to form first and second side edges of the pouch. Third and fourth lengths of the first and second sheets are sealed to each other, where the third and fourth lengths are substantially perpendicular to the drawing direction, to form first and second end edges of the pouch.

Implementations can include one or more of the following features. For example, the first and second sheets can each include a metal layer. Injecting the gas can include providing the gas to a location between the first portion of the first sheet and the first portion of the second sheet and between the first and second lengths of the sheets through a duct and a nozzle located between the first portion of the first sheet and the first portion of the second sheet and between the first and second lengths of the sheets. A transverse profile of the duct can be shaped to from the channel in the first sheet as the first sheet is drawn past the duct in the drawing direction. The first sheet can be drawn in the drawing direction through an opening between the duct and a block that together form a progressive die set, where the first sheet does not include the channel before it is drawn into the opening and where drawing the sheet through the opening forms the channel in the first sheet.

The gas can be injected as the first sheet and the second sheet are drawn in the drawing direction. Sealing the first, second, third, and fourth lengths of the first and second sheets to each other can include sealing, in a first sealing operation, the first, second, and third lengths of the first and second sheets to each other; and then sealing, in a second sealing operation, the fourth lengths of the first and second sheets to each other. The first sealing operation can include forming the first side edge, the second side edge, and the first end edge of a first pouch, and the second sealing operation can include forming the second end edge of the first pouch and forming a first side edge, a second side edge, and a first end edge of a second pouch. In addition, in a third sealing operation, fifth lengths of the first and second sheets can be sealed to each other to form a second end edge of the second pouch. The first sealing operation can include forming substantially simultaneously the first side edge, the second side edge, and the first end edge of a first pouch. the first sealing operation includes forming the first side edge, the second side edge, and the first end edge of a first pouch by pressing the first, second, and third lengths of the first and second sheets together with a linearly-translated tool. The second sealing operation can include forming the second edge of the first pouch by pressing the fourth lengths of the first and second sheets together with the tool

The first sealing operation can include, in a first continuous sealing operation, sealing the third length of the first and second sheets to each other, and then progressively sealing the first and second lengths of the first and second sheets to each other, starting from ends of the first and second lengths that are proximate to the third length, progressing along the first and second lengths, and ending with ends of the first and second lengths that are proximate to the fourth length. The first sealing operation can include forming the first side edge, the second side edge, and the first end edge of a first pouch by pressing the first, second, and third lengths of the first and second sheets together with a rotating tool, where the second sealing operation includes forming the second edge of the first pouch by pressing the fourth lengths of the first and second sheets together with the tool. The first pouch can be cut away from the second pouch.

Sealing the first, second, third, and fourth lengths of the first and second sheets to each other can include applying heat to the lengths. Sealing the first, second, third, and fourth lengths of the first and second sheets to each other can include applying pressure to the lengths.

The gas can be an insulating gas that has a lower heat conductivity than air (e.g., xenon.)

The gas can be injected at a rate such that a pressure of the gas in the pouch after the pouch has been sealed is greater than atmospheric pressure.

The first sheet can be drawn in the drawing direction through an opening in a progressive die set, where the first sheet does not include the channel before it is drawn into the opening and where drawing the sheet through the opening forms the channel in the first sheet.

The first sheet can be rolled between a pair of parallel, counter-rotating, non-cylindrical rollers, where the rollers have profiles as a function of their lengths that define the channel in the first sheet when the sheet is rolled between the rollers.

In another general aspect, a device includes a heat-dissipating component, one or more heat-generating components, where at least one heat-generating component is located in proximity to an inner surface of the heat-dissipating component, and where a gap exists between the at least one heat-generating component and the inner surface of the heat-dissipating component. The device also includes an thermal insulator, located in the gap, the insulator including a structure enclosing an insulating gas, the insulating gas having a thermal conductivity lower than air, where the structure enclosing the insulating gas includes a material having a thermal conductivity greater than air and has transverse dimension at least 1.3 times greater than a transverse dimension of the heat-generating component.

Implementations can include one or more of the following features. For example, the structure can include a material having a thermal conductivity greater than 15 Watts per meter-Kelvin or having a thermal conductivity greater than 150 Watts per meter-Kelvin. The insulating gas can have a thermal conductivity that is lower than 50% of the thermal conductivity of air. The structure enclosing the insulating gas can be in contact with the heat-generating component and in contact with the heat-dissipating component. The heat-dissipating component can include a metal (e.g, aluminum).

The thermal conductivity and dimensions of the structure can be selected such when the heat-generating component is generating heat, the heat from the heat-generating component is conducted through the structure to the heat-dissipating component and raises the temperature of the heat-dissipating component by a threshold amount, compared to when the heat-generating component is not generating heat, over an area that is greater than an area over which the temperature of the heat-dissipating component would be raised by the threshold amount in the absence of the insulator, while maintaining a peak temperature of the heat-dissipating component that is lower than a peak temperature of the heat-dissipating component that would exist in the absence of the insulator.

The dimensions and materials of the insulator can be selected such that a heat transfer rate between the heat-generating component and the heat-dissipating component is greater than in the presence of the insulator than in the absence of the insulator. The dimensions and materials of the insulator are selected such that a heat transfer rate between the heat-generating component and the heat-dissipating component is less than in the presence of the insulator than in the absence of the insulator.

### BRIEF DESCRIPTION OF THE DRAWINGS

FIG. 1 illustrates different modes of heat transfer across a gap according to an embodiment;

FIG. 2 illustrates heat transfer by conduction across the gap according to an embodiment;

FIG. 3 illustrates a temperature distribution on a surface of an enclosure without an insulator provided in the gap according to an embodiment;

FIG. 4 illustrates an insulator provided within the gap that is effective for reducing heat transfer when the gap is relatively small such that conduction dominates heat transfer according to an embodiment;

FIG. 5A illustrates a top view and a cross-sectional view of an insulator including a flexible pouch structure having a three-sided pouch seal according to an embodiment;

FIG. 5B illustrates a top view and a cross-sectional view of an insulator including a flexible pouch structure having a four-sided pouch seal according to an embodiment;

FIG. 5C illustrates a top view and a cross-sectional view of an insulator including a dual-tray structure according to an embodiment;

FIG. 5D illustrates a top view and a cross-sectional view of an insulator including a single tray structure covered with a film according to an embodiment;

FIG. 5E illustrates a top view and a cross-sectional view of an insulator including a flexible tube structure having end seals according to an embodiment;

FIG. 6 illustrates the insulator of FIG. 5D at least partially embedded into the enclosure according to an embodiment;

FIG. 7 illustrates a temperature distribution across a surface of the enclosure with and without the insulator according to an embodiment;

FIG. 8A illustrates a perspective of a laptop computer according to an embodiment; and

FIG. 8B illustrates a cross sectional view of the laptop computer depicting the insulator according to an embodiment.

FIG. 9 is a schematic diagram of a system for fabricating sealed pouches containing an insulating gas.

FIG. 10 is a schematic diagram of an example transverse profile of the material used for a pouch that contains insulating gas.

FIG. 11 is a schematic diagram of a system for forming the transverse profile in a sheet of material.

FIG. 12A is a schematic top view of the system for forming sealed pouches containing an insulating gas.

FIG. 12B is a schematic side view of the system of FIG. 12A.

FIG. 12C is a schematic diagram of a transverse profile of a sheet of material that includes a channel for receiving and containing insulating gas.

FIG. 13A is a schematic top view of the system for forming sealed pouches containing an insulating gas.

FIG. 13B is a schematic side view of the system of FIG. 12A.

FIG. 13C is a schematic diagram of a transverse profile of a sheet of material that includes a channel for receiving and containing insulating gas.

### DETAILED DESCRIPTION

An insulation solution is disclosed herein, which is effective for reducing heat transfer across relatively small gaps for electrical devices, in which conduction dominates over radiation and convection in terms of heat transfer. For example, the embodiments may provide an insulator including an insulator structure enclosing an atmospheric pressure gas or near-atmospheric pressure gas having a thermal conductivity lower than air. The insulator may be provided within a gap that exists between at least one heat-generating component and an inner surface of an enclosure of a device, where the device may be a laptop computer, a personal computer, a smart phone, or generally any type of electrical device having one or more components that generate heat, and where a user may come into contact with a heated surface. In one specific embodiment, the atmospheric pressure gas may include Xenon, which has a thermal conductivity of about 0.005 Watts per meter-Kelvin, or about 20% less than air, and may be effective for reducing heat transfer when conduction dominates over convection and radiation. However, the embodiments encompass the use of other inert gases such as Krypton, refrigerant gases, and other gases with a low thermal conductivity (e.g., lower than air).

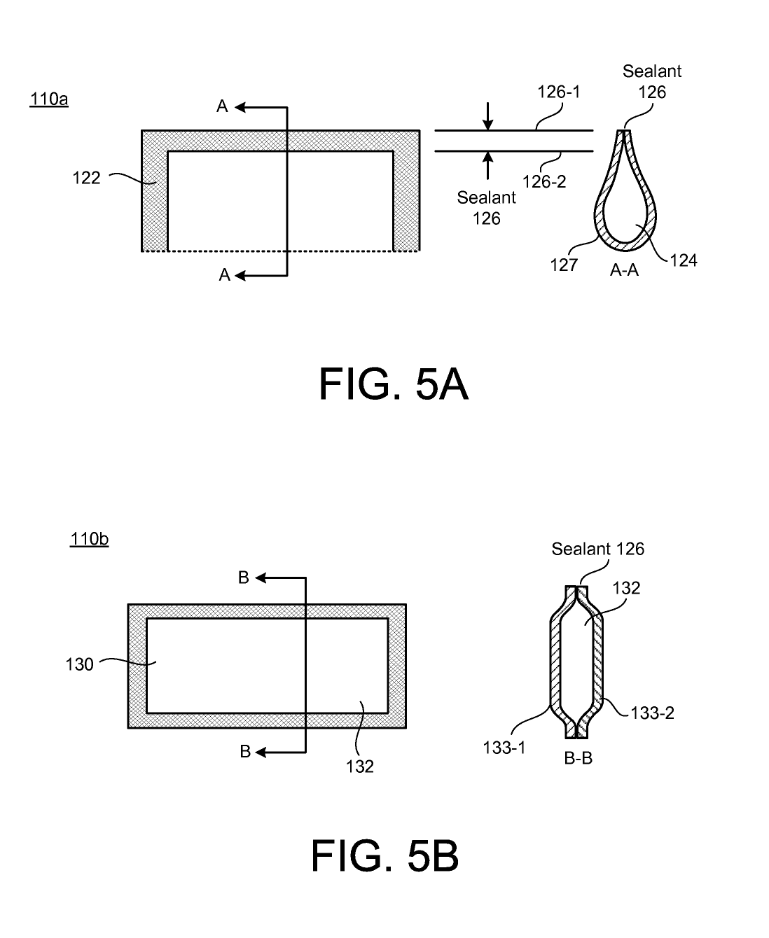

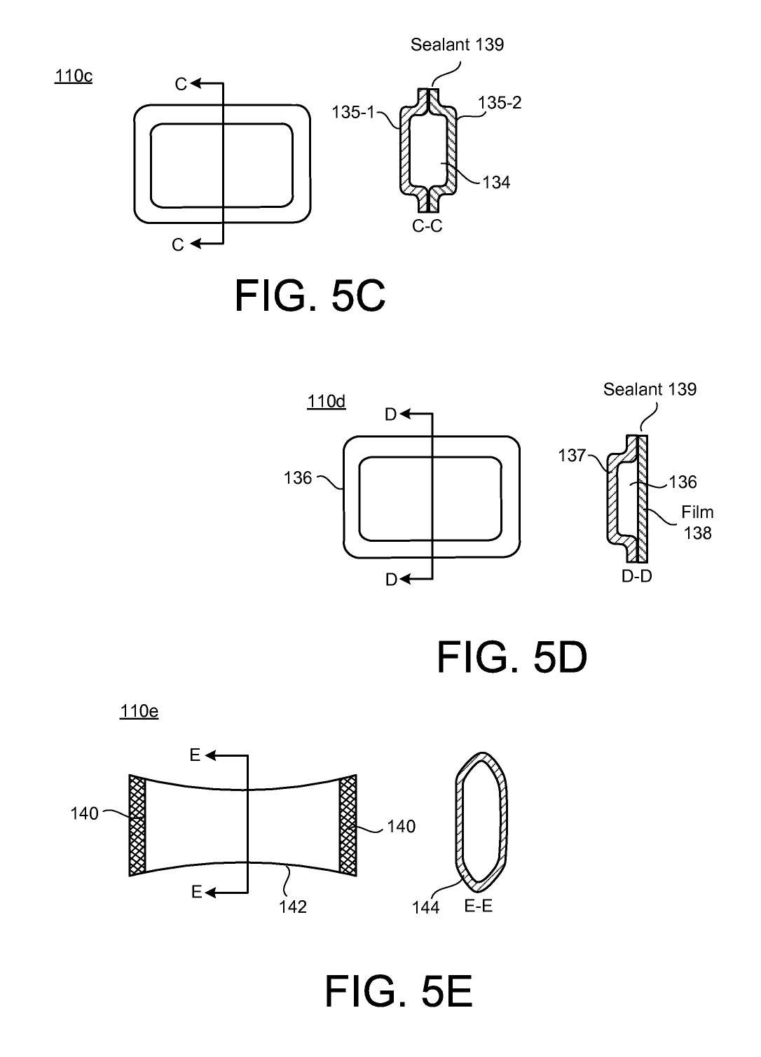

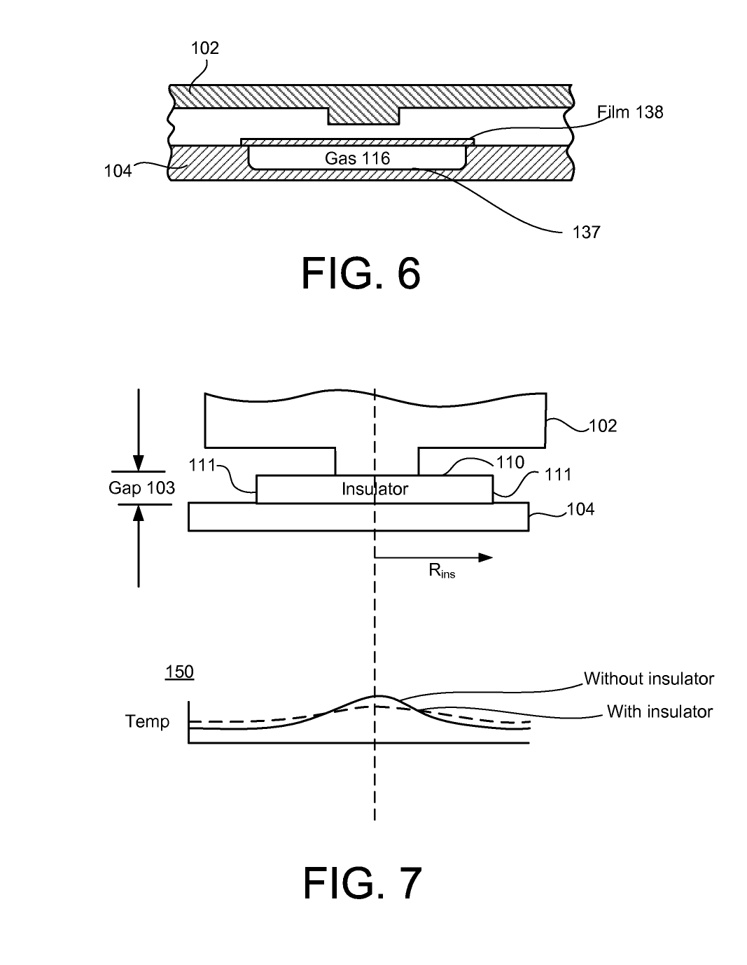

Generally, the embodiments may encompass many different types of insulator structures enclosing an atmospheric pressure gas having a thermal conductivity lower than air, e.g., a means for enclosing atmospheric pressure gas. In one example, the insulator structure (or means for enclosing atmospheric pressure gas) may include a thin-walled structure capable of housing a gas (e.g., see FIG. 4). In a more detailed embodiment, the insulator structure (or means for enclosing atmospheric pressure gas) may be a flexible pouch structure having a three-sided seal such as a flexible polymer or polymer-metal pouch similar to a juice container (e.g. catsup/mustard single serving pouch) (e.g., see FIG. 5A). Other forms may include a flexible pouch structure having a four-sided seal (e.g., see FIG. 5B), a dual tray structure (e.g., see FIG. 5C), a tray structure covered with a film/foil (e.g., see FIG. 5D), and a tube structure having end seals similar to a toothpaste casing (e.g., see FIG. 5E). Also, the insulator may be at least partially embedded into the enclosure (e.g., see FIG. 6). When embodied into an electrical device, these types of insulators may provide good insulation across gaps that are relatively small in order to reduce heat transfer when conduction dominates over radiation and convection (e.g., see FIG. 7). These and other features are further described below.

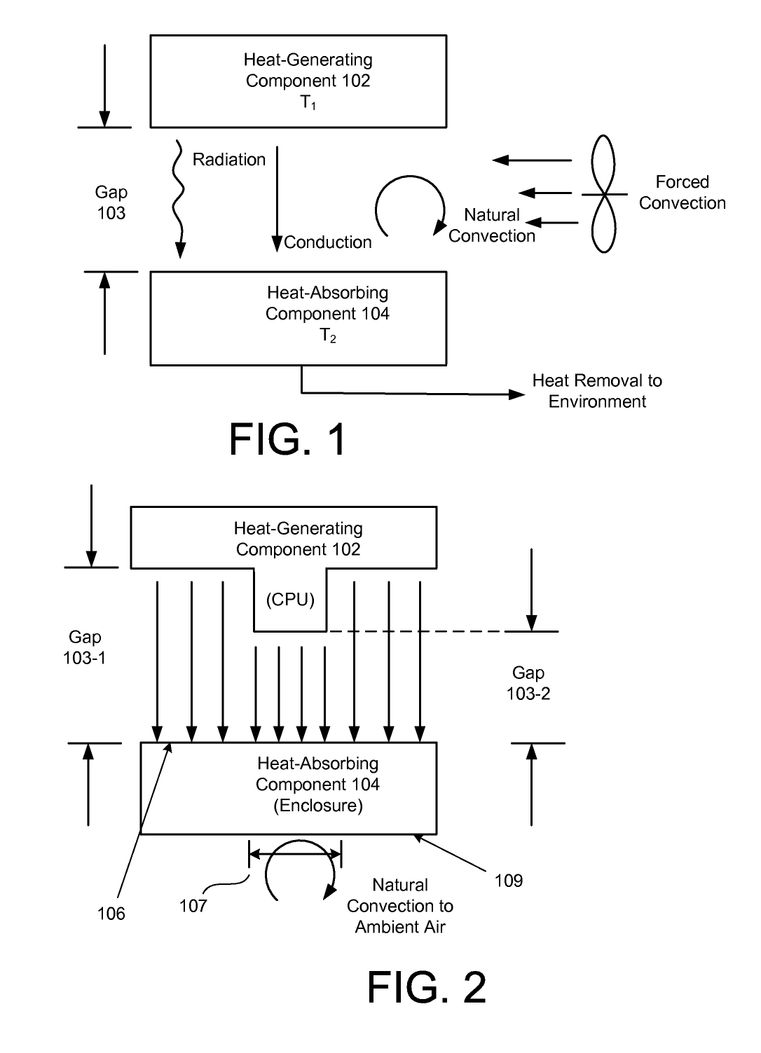

FIG. 1 illustrates different modes of heat transfer across a gap according to an embodiment. Generally, heat transfer may be accomplished through radiation, conduction, natural convection, and/or forced convection. For example, a heat-generating component 102 having a relatively high temperature (T₁) may transfer heat via a gap 103 to a heat-absorbing component 104 (also known as a heat-dissipating component) having a relatively lower temperature (T₂) via radiation, conduction, natural convection, and/or forced convection. The heat-generating component 102 may be any type of component capable of generating heat due to the operation of the component itself. In the context of electrical devices, the heat-generating component 102 may include a computer processing unit (CPU) or generally any type of component that generates heat when employed within the electrical device. The heat-absorbing component 104 may be any type of component capable of absorbing heat. In the context of electrical devices, the heat-absorbing component 104 may be a case or enclosure capable of housing the heat-generating component 102. For example, the heat-absorbing component 104 may be a metal or non-metal case that houses several electrical components.

Also, the heat-generating component 102 may include a temperature (T₁) that is higher than the temperature (T₂) of the heat-absorbing component 104. Naturally, the heat generated by the heat-generating component 102 may transfer to the lower temperature component, e.g., the heat-absorbing component 104, via radiation, conduction, natural convection, and/or forced convection, as further explained below.

Generally, heat transfer by radiation is driven by the difference between the absolute temperature of a heat emitting body (e.g., the heat-generating component 102) and one or more cooler surrounding regions (e.g., the heat-absorbing component 104), which may absorb heat from electromagnetic radiation that is derived from black body emissions, where the emissions may be a function of the absolute temperature of the heat-generating component 102. With emissivity=1 (e.g., perfect black body radiation), conduction through air dominates in the gap 103 when the gap 103 is smaller than approximately 3.7 mm, and as emissivity decreases, this crossover point increases proportionately.

Heat transfer by conduction is the transfer of heat through the material itself such as a liquid, gas, or a solid at a rate proportional to the thermal conductivity of the material, which may be relatively high for materials such as a diamond, copper, and aluminum, and lower for liquid or gas materials. Stated another way, heat transfer by conduction is the transfer of heat through the material of the gap, which may be air or any type of gas, liquid, or solid.

Heat transfer by convection is the transfer of heat from one place to another by the movement of fluids (e.g., gases, liquids). In particular, forced convection is a mechanism, or type of transport in which fluid motion is generated by an external source such as a fan. In contrast, heat transfer by natural convection (also referred to as free convection), occurs due to temperature differences between the heat-generating component 102, and the heat-absorbing component 104 which affect the density, and thus relative buoyancy, of the fluid. Convection cells are formed due to density differences within a body, where there is a circulated pattern of fluid cooling the body. In particular, the fluid surrounding the heat source receives heat, becomes less dense and rises, and then the surrounding, cooler fluid then moves to replace it. For instance, the density of a fluid decreases with increasing temperature because of volumetric expansion, which may induce natural convection flow. However, this depends on the configuration of the components, as explained below.

For example, with respect to natural convection between parallel horizontal plates in air (e.g., where the hotter plate is on top), this configuration is inherently stable because the lighter fluid is already above the cooler heavier fluid. There is no tendency for this system to move away from the state of equilibrium, and any heat transfer between the plates will be accomplished via conduction and, when closely spaced, radiation. With respect to natural convection between parallel vertical plates in air, the gap 103 has to be approximately 7 mm for natural convection to begin to matter. For example, convection cells generally cannot form when the gap 103 is less than 7 mm. As such, conduction and radiation will dominate over natural convection (i.e., free convection) from component to case when the size of the gap 103 is less than 7 mm, and conduction will dominate over natural convection and radiation from component to case when the size of the gap 103 is less than 3.7 mm.

For 1 mm gaps (which are common in laptop computers or other electrical devices), conduction also dominates heat transfer over radiation and convection. As such, as discussed herein, the size of the gap 103 when conduction dominates over radiation and convection may be approximately any size less than 3.7 mm, and may be occasionally referred to as a small gap. Also, the inventor has recognized that the size of the gap 103 affects the amount of conduction heat flow across the gap 103, as discussed with respect to FIG. 2.

FIG. 2 illustrates heat transfer by conduction across the gap 103 according to an embodiment. In this example, the heat-generating component 102 may include a CPU, and the heat-absorbing component 104 may include an enclosure that houses the CPU. A first gap 103-1 may exist between a component (or portion) of the heat-generating component 102 and an inner surface 106 of the enclosure, and a second gap 103-2 smaller than the first gap 103-1 may exist between the CPU portion and the inner surface 106 of the heat-absorbing component 104. A relatively larger conduction heat flow may exist across the second gap 103-2, and a relatively smaller conduction heat flow may exist across the first gap 103-1. As such, the heat transferred across the second gap 103-2 may result in a hotspot 107, which is a relatively hot/warm region on an outer surface 109 of the enclosure where a user may make contact. The heat transferred to the enclosure (e.g., the heat-absorbing component 104) may be subsequently transferred to the surrounding ambient air via natural convection.

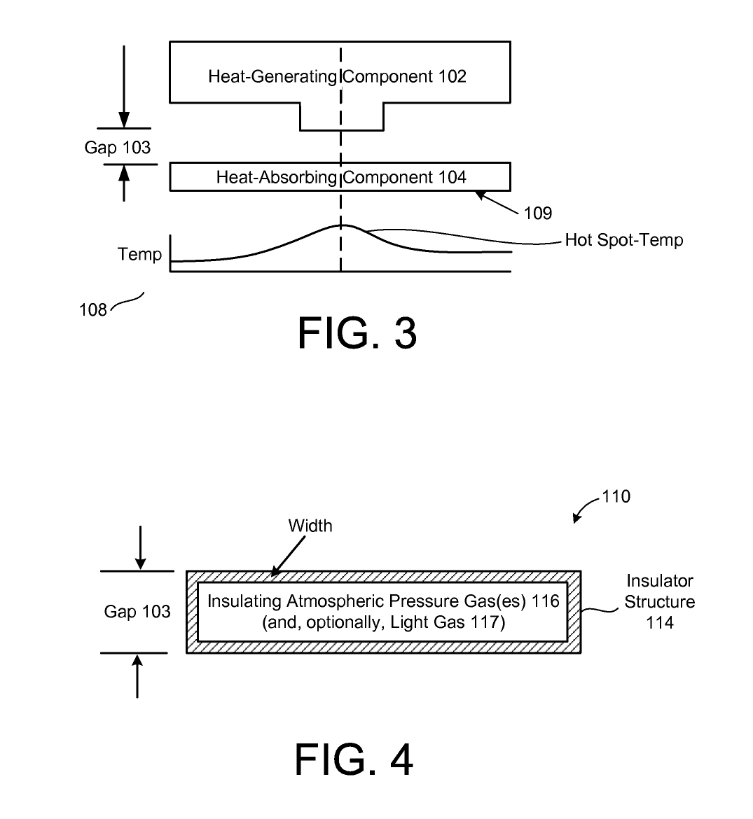

FIG. 3 illustrates a temperature distribution 108 on the outer surface 109 of the heat-absorbing component 104 without an insulator provided in the gap 103 according to an embodiment. For instance, the temperature distribution 108 shows the difference in temperature across the outer surface 109 of the heat-absorbing component 104, which increases towards the area of the hotspot 107 in FIG. 2 where the gap 103 is smaller.

An insulator may be provided in the gap 103 to reduce the amount of heat transfer when a higher amount of heat exists than what is desired. However, as demonstrated above, the size of the gap 103 affects the type of heat transfer (e.g., conduction, convection, or radiation), which affects the type of insulation used to counter the heat transfer. In one example, a hard vacuum surrounded by a metal surface may be provided as an insulator, which is effective for eliminating convection and conduction. However, the problem of insulating with a vacuum is that for any kind of flat application atmospheric pressure tends to collapse the container walls. This may be countered by posts or pillars, however, the posts or pillars typically end up becoming a major heat leak, reducing the performance of the vacuum insulator.

For relatively larger gaps, adding insulation such as fiberglass is relatively effective because the fiberglass breaks up the ability of the convection cells to form, thereby preventing heat transfer by convection. As such, with larger gaps, insulation such as fiberglass or low density styrene foam, or urethane forms is useful because they reduce heat transfer by convection. Although these types of insulators are effective to prevent heat transfer by natural convection/radiation, they still allow conduction flow through the gaps that are filling the insulation, and then through the insulation material itself. Because most solids have higher thermal conductivity as compared to gases, conventional insulators typically use a low density material such as loose fiberglass or aerogel that is mostly gas. Also, with respect to reducing heat transfer by radiation, solutions such as MLI (multi-layer insulation) have been utilized. MLI may consist of many layers of a reflective material in tiny gaps for purposes of insulating in vacuums or with large temperature differences (e.g., aerospace and some exotic automotive under-hood applications).

However, the difficulty increases when the gaps are relatively small such as approximately less than 3.7 mm, and increases when the gaps are even smaller such as approximately equal to or less than 1 mm. Generally, within electrical devices such as laptop computers, personal computers, and smart phones, smaller gaps (e.g., less than 2 mm) are more common due to market pressures of creating smaller and thinner devices. In this context, for small gaps, convection cells cannot form. Therefore, preventing heat transfer by convection is no longer important. Essentially, the small gap contains stagnant air, and if at least a portion of the stagnant air in the gap 103 is replaced by an insulator such as a solid, it makes matters worse because the solid-based insulator has higher thermal conductivity than air. Therefore, insulating small gaps with foam and/or fiberglass will not be effective for reducing heat transfer across the gap 103. Even nanopore insulation materials that depend on the Knudsen effect suffer from this limitation. As such, instead of placing a solid based material for use as an insulator in the gap 103, the embodiments encompass providing an insulator structure enclosing an atmospheric pressure gas with a thermal conductivity lower than air for use as an insulator, as further discussed below.

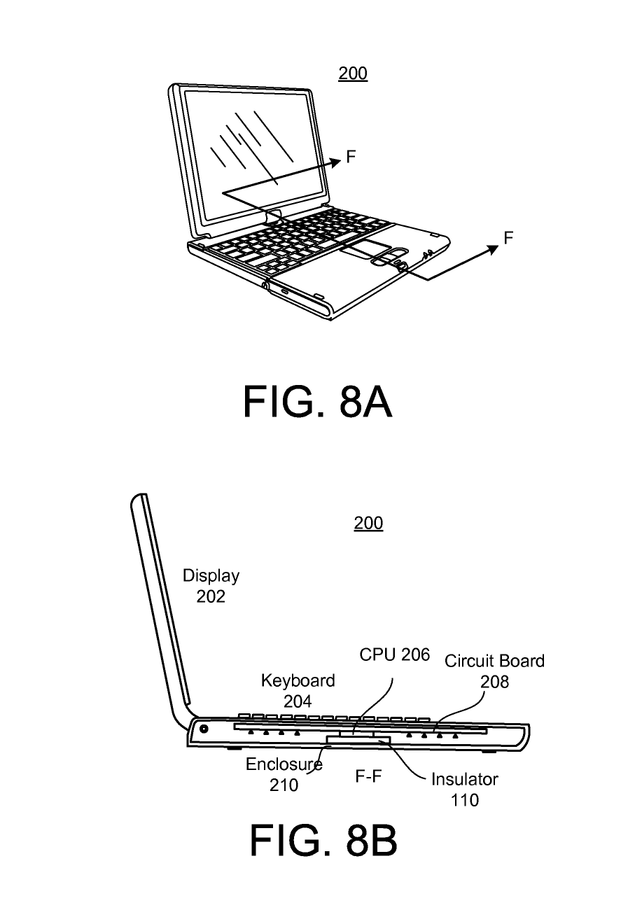

FIG. 4 illustrates an insulator 110 provided within the gap 103 that is effective for reducing heat transfer when the gap 103 is relatively small such that conduction dominates heat transfer according to an embodiment. For example, the insulator 110, located in the gap 103, may include an insulator structure 114 enclosing one or more atmospheric pressure gases 116, where the one or more atmospheric pressure gases 116 may have a thermal conductivity lower than air. In one embodiment, the atmospheric pressure gas 116 may include Xenon, which has a thermal conductivity 20% of air and may be effective for reducing heat transfer when conduction dominates over convection and radiation. However, the embodiments encompass the use of other inert gases such as Krypton, refrigerants, and other gases that have a thermal conductivity lower than air. Generally, the insulator structure 114 may be a container capable of housing a gas, where the container has a thickness (Width). As such, when employed with an electrical device such as a laptop computer (shown in more detail with respect to FIG. 8), the insulator 110 may reduce local heat transfer, reduce localized hotspots, and improve the user experience. However, the insulator 110 may be applied to any application where a planar source (e.g., the heat-generating component 102) and a heat sink (e.g., the heat-absorbing component 104) meet across a gap. In one example, the insulator 110 may protect any kind of heat-sensitive component within an enclosure.

It is noted that the insulator 110 may be filled with one type of atmospheric pressure gas 116 such as a Xenon, or include multiple types of atmospheric pressure gases 116 such as Xenon and Argon, as further explained below. In addition, it is noted that the insulator 110 (over time) may include other types of gases, which have permeated into the insulator structure 114, which is also further discussed below.

The insulator structure 114 may include a single material that is arranged to enclose the atmospheric pressure gas 116 having a thermal conductivity lower than air. For instance, the insulator structure 114 may include a flexible material such as a polymer or polymer-metal based material, or a metal-based material such as steel or aluminum, for example. Also, the insulator structure 114 may include a plurality of layers such one or more layers of the polymer or polymer-metal based material and one or more layers of the metal-based material. In some examples, one or more of the layers may be bonded to itself or another layer using a sealant such that a cavity exits inside the structure, where the cavity is then filled with the atmospheric pressure gas 116 having a thermal conductivity lower than air.

With respect to the width of the insulator structure 114, ideally the material(s) that constitute the insulator structure 114 has zero thickness, e.g., all the space is reserved for the atmospheric pressure gas 116. Generally, since the material(s) that constitute the insulator structure 114 have a higher thermal conductivity than the atmospheric pressure gas 116, the material(s) may be considered a thermal short-circuit that reduces the gap by a corresponding thickness (Width). For the gap 103 having a length less than 1 mm, the thickness of the material(s) are critical, and, in one embodiment, the thickness of the insulator structure 114 may be in the range of 12-120 microns to be effective for reducing heat transfer when conduction dominates over radiation and convection.

Also, according to another embodiment, the insulator structure 114 may include not only the one or more atmospheric pressure gases 116 having a thermal conductivity lower than air such as Xenon (and Argon), but also a light gas 117 such as helium or hydrogen, for example. In words, the Xenon-filled or other gas-filled insulator structure 114 may be infused with a relatively small amount of the light gas 117 such as helium or hydrogen. In contrast to Xenon or the other atmospheric pressure gases discussed herein, helium and hydrogen have a relatively high thermal conductivity, which may be six times that of air. As such, one of ordinary skill in the art may consider it counter-intuitive to include the light gas 117 in the insulator structure 114, which is designed to prevent heat transfer across the gap 103 when conduction dominates over convection and radiation. For instance, the inclusion of the light gas 117 actually increases thermal conductivity—not reduces it.

However, the inclusion of the light gas 117 into the insulator structure 114 containing Xenon and/or other atmospheric gasses discussed herein allows a person to detect the leakage of the insulator structure 114 in a fairly easy manner. For example, helium or hydrogen has a property that it escapes very easily, and will transfer through even solid metals at a measurable rate. In particular, mass spectrometer leak detectors have been developed to detect miniscule quantities of gas (e.g., helium) leakage by applying a vacuum to the outside of a vessel filled with, and then using the mass spectrometer leak detector to detect individual molecules or atoms in the pumped exhaust of the detector. As such, according to an embodiment, a certain percentage of the light gas 117 may be infused into the insulator structure 114 for performing one or more non-destructive tests with the insulator structure 114, and to determine if the insulator structure 114 has any very small leaks that might affect its service life.

In one particular embodiment, the atmospheric pressure gas 116 may be intentionally spiked with the light gas 117 such as approximately 2% of the light gas 117 by weight. The 2% of the light gas 117 may increase the thermal conductivity of the atmospheric pressure gas 116 by approximately 20%. However, because the light gas 117 escapes relatively easier, the insulator 110 of the embodiments will actually improve over the lifespan of the insulator 110 as the light gas 117 disappears from the insulator structure 114 over time. Also, the inclusion of the light gas 117 may provide an effective mechanism for performing a leak test on the insulation material at the end of the production line.

As indicated above, the insulator structure 114 may include multiple types of atmospheric pressure gases 116 having a thermal conductivity lower than air. For example, the insulator structure 114 may include a secondary atmospheric pressure gas (e.g., Argon) besides the primary atmospheric gas 116 (e.g., Xenon). This secondary atmospheric pressure gas may include Argon or a similar type of gas, which has a higher permeation rate than the primary atmospheric pressure gas (Xenon). Also, the outward permeation rate of the secondary atmospheric pressure gas may be similar to the inward permeation rate of gases that are outside the insulator structure 114 (e.g., similar permeation rate to nitrogen and/or oxygen). However, the thermal conductivity of the secondary atmospheric pressure gas may be sufficiently low to not have an excessive effect on the overall thermal conductivity of the gas mixture (e.g., lower than air). Permeation of a particular gas is driven by the partial pressure on each side of a barrier. A particular gas moves from a region with a higher partial pressure to a region of lower partial pressure, regardless of the total pressure. This is why a helium-filled latex balloon quickly deflates even though the total pressure inside and outside the balloon is very similar.

For example, assuming that the primary atmospheric pressure gas 116 is Xenon, Xenon has a relatively large molecule, which has a low permeation rate through the insulator structure 114. In other words, Xenon tends to stay within the insulator structure 114, and not leak outside the structure. However, other gases such as oxygen and nitrogen can permeate into the insulator structure 114 (e.g., oxygen and nitrogen have a smaller molecule and may permeate into the insulator structure 114), and may increase the size of the insulator structure 114 and cause the structure to swell. The enlarged size of the insulator structure 114 may interface with surrounding components. For example, over time, the insulator structure 114 may result in an oversized pouch (e.g., the increased size due to the addition of the oxygen and/or nitrogen), which may affect the operation of the device or other components within the device.

As such, according to the embodiments, the insulator structure 114 may include Xenon and, optionally, the light gas 117, but also a secondary atmospheric pressure gas such as Argon, which has a thermal conductivity lower than air (e.g., about 50% lower, but higher than Xenon) and a permeation rate similar to nitrogen and oxygen. Therefore, the insulator 110 may include two types of atmospheric pressure gases having a thermal conductivity lower than air. However, the secondary atmospheric pressure gas (e.g., Argon) may have a higher thermal conductivity than Xenon (or any other similar atmospheric pressure gas 116), but still sufficient enough to be effective for reducing heat transfer across the gap 103. Further, the secondary atmospheric pressure gas may have a permeation rate higher than Xenon, and, perhaps, similar to oxygen and/or nitrogen. As a result, as the oxygen and/or nitrogen permeate into the insulator structure 114, the secondary atmospheric pressure gas (e.g., Argon) is permeating out of the insulator structure 114, thereby keeping the insulator structure 114 around the same (or substantially similar) size.

FIGS. 5A-5E illustrate the insulator 110 having the insulator structure 114 enclosing the atmospheric pressure gas 116 according to a number of different embodiments. Although FIGS. 5A-5E illustrate specific embodiments of the insulator structure 114, the embodiments may include any type of structure enclosing the atmospheric pressure gas 116, e.g., the general insulator structure of FIG. 4.

In one example, FIG. 5A illustrates a top view and a cross-sectional view of an insulator 110a including a flexible pouch structure having a three-sided pouch seal according to an embodiment. The flexible pouch structure may include a polymer or polymer-metal material that is arranged in a “pouch”, which is heat sealed along three-sides using a sealant 126. The left portion of FIG. 5A illustrates the top view of the flexible pouch structure, and the right portion of FIG. 5A illustrates a cross-sectional view taken across the section line A-A. In this example, a single portion 127 of the polymer or polymer-metal material may be folded in half, and the sealant 126 is used along three-sides of a heat-sealed area 122 of the insulator 110a in order to seal the pouch structure, thereby creating a pouch. The sealant 126 may include an adhesive, solder, or any type of sealant known in the art that is effective for sealing a polymer, polymer-metal, or metal material. The bursting strength of the seals may be strong enough to survive transient overpressure when the system is dropped on a hard surface. As a result, a cavity 124 inside the flexible pouch structure exists, and is filled with the one or more atmospheric pressure gases 116 having a thermal conductivity lower than air, e.g., Xenon, Argon, as well as possibly the light gas 117 shown in FIG. 4.

According to one embodiment, the flexible pouch material may include a plurality of layers such as a printable polymer outer-layer, an aluminum layer, inner polymer layer, and one or more adhesive or heat-sealed layers. The flexible pouch structure may be formed by placing continuous rolls of the flexible pouch material through a machine which heat seals the plurality of layers, and seals the three-sides of the flexible pouch structure, thereby producing the flexible pouch structure having a three-sided seal similar to a single serving mustard package.

According to another embodiment, the flexible pouch material may include a polymer or polymer-based layer and a barrier layer such as metal, glass, or a ceramic. For example, a polymer or polymer-based layer may be considered highly permeable to the atmospheric pressure gas 116 used in the insulation layer, and permeable to gases in general. As such, in order to reduce the ability of the atmospheric pressure gas 116 to permeate through the package, the package film can incorporate a barrier layer that is developed from metal, glass, or a ceramic, which are generally considered impermeable to gasses. In one particular embodiment, the barrier layer may include a thin layer of aluminum foil, where the thickness of the aluminum foil still permits the insulator structure 114 to be flexible (e.g., in the range of about 20 microns to about 40 microns thick). In another embodiment, the barrier layer may include a glass or ceramic or silicon dioxide layer. However, in the glass or ceramic or silicon dioxide layer approach, this layer tends to crack, which allows the gas to pass through the cracks in the film without going through the glass or ceramic or silicon dioxide material, and then those leaks dominate the transport of gas out of the insulator structure 114.

FIG. 5B illustrates a top view and a cross-sectional view of an insulator 110b including a flexible pouch structure having a four-sided seal according to an embodiment. The flexible pouch structure of the insulator 110b may include the flexible pouch material, described above with reference to the insulator 110a. However, the flexible pouch material is sealed along four-sides using the sealant 126. The left portion of FIG. 5B illustrates the top view of the pouch structure having the four-sided seal, and the right portion of FIG. 5B illustrates a cross-sectional view taken across the section line B-B. In this example, two portions (e.g., a first portion 133-1 and a second portion 133-2) of the flexible pouch material may be sealed together using the sealant 126 along four sides of a heat-sealed area 130 of the insulator 110b in order to seal the pouch structure, thereby creating a pouch. As a result, a cavity 132 inside the pouch structure exists, which is filled with the one or more atmospheric pressure gases 116 having a thermal conductivity lower than air, e.g., Xenon, Argon and, optionally, the light gas 117.

The insulator 110a and the insulator 110b may be applied as insulators to provide insulation over a specified area, e.g. such as a heat-generating component 102 that generates a relatively large amount of heat that creates a hotspot that may contact with the user.

FIG. 5C illustrates a top view and a cross-sectional view of an insulator 110c including a dual-tray structure according to an embodiment. For example, the left portion of FIG. 5C illustrates a top view of the dual-tray structure, and the right portion of FIG. 5C illustrates a cross-sectional view taken across the section line C-C. In this example, a first tray structure 135-1 and a second tray structure 135-2 may be bonded together such that a cavity 134 exists between the first tray structure 135-1 and the second tray structure 135-2, where the cavity 134 is filled with the one or more atmospheric pressure gases 116 having a thermal conductivity lower than air and, optionally, the light gas 117. The first tray structure 135-1 and the second tray structure 135-2 may be bonded together with a sealant 139. The sealant 139 may include the types of sealants with respect to sealant 126, or a solder weld, for example. The second tray structure 135-2 may be symmetrical to the first tray structure 135-1, or vice versa.

Further, each of the first tray structure 135-1 and the second tray structure 135-2 may include a flat portion with raised edges. Also, each of the first tray structure 135-1 and the second tray structure 135-2 may be composed of aluminum, stainless steel, copper, or other metals, or of metal and polymer composite films, which may be configured as a tray. In one example, a thickness of each of the first tray structure 135-1 and the second tray structure 135-2 may be in the range of 20 microns to 100 microns, generally. Also, it is noted that if the thickness of the metal in the tray structure is too thin, the metal may include one or more pin holes, which allow the atmospheric pressure gas 116 to escape or atmospheric gasses to penetrate the package.

FIG. 5D illustrates a top view and a cross-sectional view of an insulator 110d including a single tray structure 137 covered with a film 138 according to an embodiment. The left portion of FIG. 5D illustrates a top view of the insulator 110d, and the right portion of FIG. 5D illustrates a cross-sectional view taken across the line D-D. In one embodiment, the film 138 may be a non-metallic film such as any type of plastic material. Alternatively, the film 138 may be a metallic foil such as aluminum or stainless steel, for example. Similar to the first and second tray structures 135, the single tray structure 137 may include a stainless steel, aluminum, copper, or other metal tray, or metal-polymer composite that is arranged as a flat portion with raised edges. However, in this embodiment, only a single tray structure 137 is used. The film 138 may be heat-sealed to the single tray structure 137 using the sealant 139 such that a cavity 136 exists between the film 138 and the single tray structure 137, where the cavity 136 is filled with the one or more atmospheric pressure gases 116 having a thermal conductivity lower than air and, optionally, the light gas 117.

FIG. 5E illustrates a top view and a cross-sectional view of an insulator 110e including a flexible tube structure 144 (e.g., similar to toothpaste tubing) having end seals 140 according to an embodiment. The left side of FIG. 5E illustrates a top view of the insulator 110e, and the right side of FIG. 5E illustrates a cross-sectional view taken across the section line E-E. In this example, the tubing structure 144 may include a flexible tube material such as a polymer or polymer-metal material that is arranged in a circular form, where inside the tubing exists an initially circular cavity 142 that is filled with the atmospheric pressure gas 116 having a thermal conductivity lower than air. Both ends of the tubing structure 144 are sealed with the sealant 126 as shown with respect to the top view of the insulator 110E. The tube may be flattened in service to fit within the gap 103.

FIG. 6 illustrates the insulator 110d of FIG. 5D at least partially embedded into the heat-absorbing component (e.g., the enclosure) according to an embodiment. For example, in FIG. 6, the insulator 110d may be at least partially embedded into the enclosure of the device. In particular, the single tray structure 137 may be embedded into the heat-absorbing component 104, e.g., the enclosure of a device. The film 138 may be provided over the surface of the heat-absorbing component 104, which encloses the single tray structure 137. It is also noted that the insulator 110c of FIG. 5C may be arranged in a similar manner, e.g., at least a portion of one of the first tray structure 135-1 and the second tray structure 135-2 may be embedded into the enclosure.

FIG. 7 illustrates a temperature distribution 150 across a surface of the heat-absorbing component 104 with and without the insulator 110 according to an embodiment. For example, in FIG. 7, the insulator 110 is provided within the gap 103 existing between the heat-generating component 102 and the heat-absorbing component 104. As shown in FIG. 7, the insulator 110 is effective for reducing the peak temperature on the surface of the heat-absorbing component 104, when the gap 103 is small enough such that conduction dominates heat transfer over radiation and convection. In contrast, filling the gap 103 with air, and without the insulator 110 of the embodiments may result in a higher surface temperature in the area of the hotspot 107 (as shown in FIG. 1).

The insulator 110 may have side walls 111 that connect a top wall in thermal contact with the heat-generating component 102 and a bottom wall in thermal contact with considered the heat-dissipating component 104. Although the insulator 110 may be filled with a gas having a thermal conductivity lower than air, the sidewalls of the insulator 110 may have a thermal conductivity higher than air, and the sidewalls therefore may conduct heat from the heat-generating component 102 to the heat-dissipating component 104. For example, the sidewalls may include aluminum (with thermal conductivity of about 205 W per meter-Kelvin), aluminum oxide (with a thermal conductivity of about 30 W per meter-Kelvin), copper (with a thermal conductivity of about 400 W per meter-Kelvin), stainless steel (with a thermal conductivity of about 16 W per meter-Kelvin), or other materials having a thermal conductivity greater than air.

In some implementations, this may be advantageous because it may allow heat to be transferred away from the heat-generating component 102 to the heat-dissipating component 104, while spreading the heat over a relatively large area of the heat-dissipating component 104 and thus avoiding a hotspot having a high peak temperature on the heat-dissipating component 104. In some implementations, when the transverse dimension of the insulator (e.g., the radius, Rᵢₙₛ, of the insulator when the insulator is disk-shaped) is larger than a critical transverse dimension (e.g., the radius, R_{crit}, of the insulator when the insulator is disk-shaped), then the heat transfer rate from the heat-generating component 102 to the heat-dissipating component 104 is higher than the heat transfer rate in the absence of the insulator, and the hotspot may have a higher temperature than in the absence of the insulator. The critical transverse dimension depends parameters such as the size and dimensions of the insulator, the material, size, and dimensions of which the insulator, and the gas(es) with which the insulator is filled. For example, when the walls of the insulator are relatively thick and when a high thermal conductivity material is used for the walls of the insulator, the critical transverse dimension may be relatively low. In contrast, when the walls of the insulator are relatively thin and when a low thermal conductivity material is used for walls of the insulator, the critical transverse dimension may be relatively high.

In some implementations, when a transverse dimension of the insulator is sufficiently large compared to a transverse dimension of the heat-generating component 102, heat from the heat-generating component can be transferred through the insulator to the heat-dissipating component 104 to a larger area of the heat-dissipating component then in the absence of the insulator. In some implementations, the transverse dimension of the insulator can be 1.3 times greater than a transverse dimension of the heat-generating component. In other implementations the transverse dimension of the insulator can be 1.5, 2.0, 3.0 times greater than a transverse dimension of the heat-generating component. For example, heat can be conducted through the structure to the heat-dissipating component and can raise the temperature of the heat-dissipating component by a threshold amount, compared to when the heat-generating component is not generating heat, over an area that is greater than an area over which the temperature of the heat-dissipating component would be raised by the threshold amount in the absence of the insulator. At the same time, when the insulator is present within the gap between the heat-generating component and the heat-dissipating component, a peak temperature of the heat-dissipating component can be lower than a peak temperature of the heat-dissipating component that would exist in the absence of the insulator.

FIG. 8A illustrates a perspective of a laptop computer 200, and FIG. 8B illustrates a cross sectional view of the laptop computer 200 taken across the section line F-F according to an embodiment. As shown in FIG. 8B, the laptop 200 may include a display 202, a keyboard portion 204, and an enclosure 210 housing a circuit board 208 having one or more CPUs 206. The enclosure 210 may be considered the heat-absorbing component 104, and the one or more CPUs 206 may be considered the heat-generating component 102, of the previous figures. A gap may exist between one or more CPUs 206 and an inner surface of the enclosure 210. According to the embodiments, the insulator 110 may be located, within the gap, between the CPU 206 and the inner surface of the enclosure 210. As indicated above, the insulator 110 may include the insulator structure 114 encompassing the atmospheric pressure gas 116 having a thermal conductivity lower than air. The insulator structure 114 may include a generic structure as discussed with reference to FIG. 4, or any of the more specific embodiments of FIGS. 5-6.

Further consideration is now given to techniques for fabricating the pouches described above. Because gas impurities in a pouch filled with an insulating gas (e.g., xenon) can significantly reduce the thermal insulation capability of the pouch, it is desirable to fill the pouches with little contamination of background gases (e.g., oxygen, nitrogen). However, because many insulating gases are relatively expensive, techniques for creating pouches filled with an insulating gas should use the supply of xenon economically and waste as little gases possible. In addition, pouches filled with an insulating gas must use films and seals that have very low permeability, so that atmospheric gases do not leak in and the insulating gas does not leak out over the intended lifetime of the pouch.

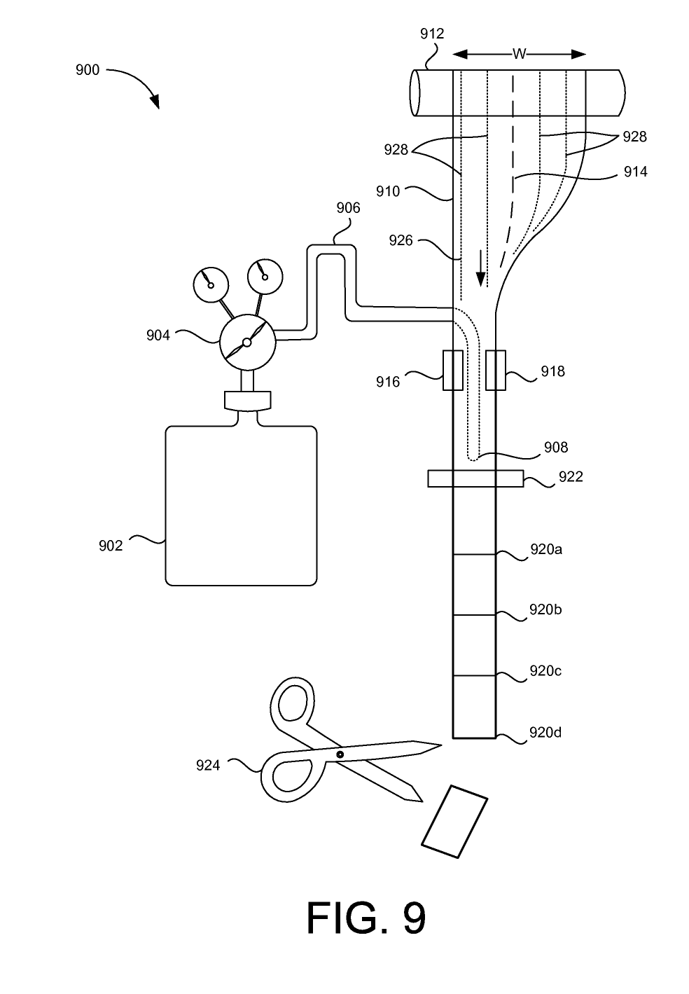

FIG. 9 is a schematic diagram of a system 900 for fabricating sealed pouches containing an insulating gas. The system includes a container 902 holding the insulating gas. Gas from the container 902 flows through a regulator 904 that regulates the flow rate of the gas and into a passageway 906 (e.g., a tube) that is open at one end 908 to deliver gas to a region where the pouches are formed.

The system 900 also includes a material 910 that is used to enclose the pouches and to contain the insulating gas. The material 910 can be a flexible film that is sufficiently impermeable to contain a sufficient concentration of the insulating gas in, and to exclude atmospheric gas from, the pouch for the lifetime of the pouch (e.g., greater than 30,000 hours). For example, the material can include a metal (e.g., aluminum) film layer having sufficient thickness and integrity to maintain a specific gas composition within a pouch created from the material for the lifetime of pouch. For example, the material 910 may include an aluminum layer having a thickness of 20 μm or more.

The material 910 can be supplied to the region where the pouches are formed in a number of different ways. For example, as shown in FIG. 9, the material 910 can be supplied as a sheet on a roller 912, and that is unrolled from the roller 912 and fed to the region where the insulating gas exits the nozzle 908 of the passageway 906. In some implementations, the width, W, of the material 910 on the roller 912 can be more than twice the width of the finished pouches, and after the material 910 is unrolled from the roller 912, the material can be folded over itself along a fold line 914. For some materials 910, the fold line 914 can be defined by scoring, perforating, or even slitting the material along the fold line. The scoring, perforating, slitting can be performed in-line, while the material 910 is being fed off the roller 912, or can be performed off-line, e.g., before the material 910 is rolled onto the roller 912 or before the material is fed through the sealing mechanisms described below, which form sealed pouches of insulating gas contained within the material 910. In other implementations, it may be unnecessary to score, perforating, or slit the material 910 along the fold line 914, and the material may be folded along the fold line 914 without otherwise altering the integrity of the material 910 at the fold line 914.

After the material has been folded along the fold line 914, opposite edges of the material 910 are in close proximity to one another, such that two sheets of the material 910 are in close proximity to each other and can be sealed against each other by a sealing mechanism. For example, the sealing mechanism can include a heated roller or plate 916 that can heat seal the opposite edges of the material against each other. Another heated roller or plate 918 can create a heat seal of different sides of the material along the fold line 914. In other implementations, one or more adhesive materials can be used to seal opposite edges of the material to each other and to create a seal along the fold line. In still other implementations, a combination of heat and adhesive materials can be used to create the seals. In still other implementations, heat can be applied to create a heat seal independent of the rollers 916, 918. For example, the rollers can be used to press the different sides of the material together, and then heat can be applied to seal the different sides of the material. In other implementations, the seals can be created by soldering, brazing, welding, etc. the different sides of the material together to create a gas-impermeable seal.

In some implementations, to create the two sheets of material that are in close proximity to each other near the rollers 916, 918, rather than using a single roll of material and then folding the material in half along a fold line 914, two rolls of material can be used, and the sheets of material from the two different rolls can be placed into close proximity to each other near the rollers 916, 918, while still allowing the insulating gas passageway 906 to extend between the two sheets of material. In other implementations, the material 910 need not be fed from a roll 912, but can be fed as a flat sheet toward the sealing mechanism (e.g., 916, 918). The sealing mechanism simultaneously forms the top of the last pouch and the beginning of the next pouch.

End seals 920a, 920b, 920c, 920d can be formed in the material 910 by an additional sealing mechanism 922. Thus, the sealing mechanism 922 can seal top and bottom layers of the material 910 along a line that is perpendicular to the direction 926 in which the material 910 is fed. The sealing mechanism 922 can be located close to the end 908 of the insulating gas passageway 906, so that after one end seal (e.g., 920b) is formed, then insulating gas is fed into the area within the two sheets of material 910 as the material is fed along the production line (e.g., as the material 910 is unrolled from the roller 912 and is moved downward in FIG. 9). Then, after the material has been fed a predetermined distance, a subsequent end seal is formed (e.g., seal 920a), so that insulating gas is completely sealed within a pouch defined by two end seals (e.g., seal 920b and seal 920a) and two edge seals (e.g., the seals formed by the sealing mechanisms 916, 918). After sealed pouches have been formed, the material can be cut by a cutting mechanism 924 along the midpoint of each end seals to create individual pouches filled with insulating gas.

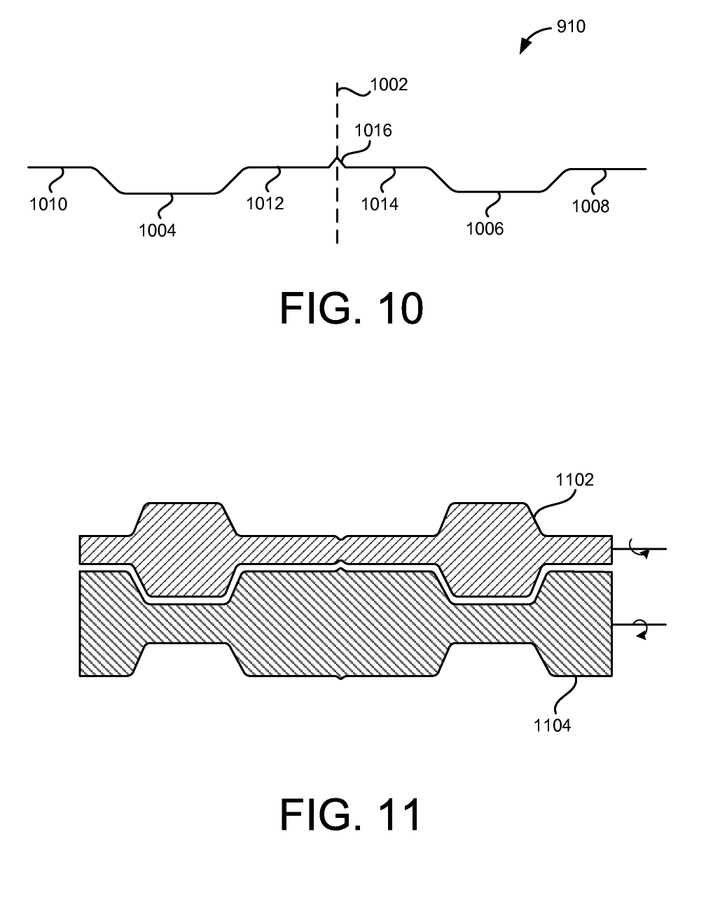

In some implementations, a transverse profile (i.e., a profile in the direction that is transverse to the feed direction 926 of the material in FIG. 9) can be formed in the material 910 before the top and bottom sheets of the material are sealed together by the sealing mechanism, so that sealing of the edges of the material is facilitated and so that the shape of the pouch can be consistently defined. FIG. 10 is a schematic diagram of an example transverse profile of the material.

In some implementations, the transverse profile can be formed in the material before it is rolled onto roller 912. FIG. 10 is a schematic diagram of an example transverse profile 1000 of the material 910. In some implementations, the transverse profile can be symmetric about a fold line 1002, about which the material is folded. The transverse profile can have channels 1004 and 1006, which mate with each other when the material 910 is folded about the fold line 1002 to form a pouch that can contain an insulating gas. The transverse profile can have first flat sections 1010 and 1008, and second flat sections 1012 and 1014, which mate with each other, respectively, when the material is folded about the fold line 1002 and which can be sealed against each other to create a gas impermeable pouch that defines a cavity within the channels 1004, 1006 when the channels mate with each other. To facilitate folding about the fold line, the transverse profile of the material can include a feature 1016 (e.g., a scoring, perforation, or slitting of the material), where the feature 1016 is located on the fold line 1002.

The transverse profile of the material 910 can be formed in a variety of ways. For example, in one implementation, FIG. 11 is a schematic diagram of a system 1100 for forming the transverse profile in a sheet of material. The system 1100 can include a top roller 1102 and a bottom roller 1104 between which the material 910 is rolled. The top roller 1102 can rotate in one direction about a central axis of the roller, while the bottom roller up rotates the opposite direction about a central axis of the roller. Each roller 1102, 1104 can be cylindrically symmetric about a central axis of the roller and the profile of the roller along the length of the roller can be chosen such that the profile as a function of length approximates the desired transverse profile of the sheet shown in FIG. 10. Thus, as a flat sheet of material 910 is rolled between the rollers 1102, 1104, the flat sheet is deformed into a sheet having the transverse profile shown in FIG. 10. In some implementations, the material 910 can be rolled between a series of roller pairs, which successively convert the transverse profile of the material from a flat sheet into a sheet having the transverse profile shown in FIG. 10. For example, each pair of rollers may deform the profile of the sheet a bit more than the previous pair until the desired transverse profile is achieved. In some implementations, the roller pairs, rather than having complementary profiles along their lengths as shown in FIG. 11, may include a first roller that includes a transverse profile whose radius varies along the length of the roller (e.g., a profile that matches the desired profile 1000 of the material) and a second roller composed of soft, deformable material that can deform into a profile that is complementary to the first roller's profile when the first roller is pressed against second roller with the material between the two rollers.

The channels 1004, 1006 can be formed in the material 910 at different stages within the processing of the material. For example, referring again to FIG. 9, the channels can be formed in the material 910 before the material is loaded onto the roller 912. Then, when the material 910 is unrolled from the roller and said downstream in the direction 926 for processing the channels, shown by dotted lines 928 in FIG. 9 can be used to form the pouches when side and edge seals are created by the sealing mechanisms shown in FIG. 9. In another implementation, the material on the roller 912 can be unformed (i.e., flat), and after the material is unrolled from the roller 912 and before the material is folded over itself, the channels can be formed in the material (e.g., using techniques described in reference to FIG. 11).

In some implementations, a channel may be formed only in one side of a pouch. For example, referring again to FIG. 10, the transverse profile of the material may include channel 1004, but channel 1006 may be missing, such that the material is flat between portion 1014 and portion 1008. Then, when the material is folded about fold line 1002 and seals are formed between portion 1008 and 1010 and between portion 1012 and portion 1014, respectively, a pouch can be formed by the channel 1004 with a flat sheet of material over the channel.

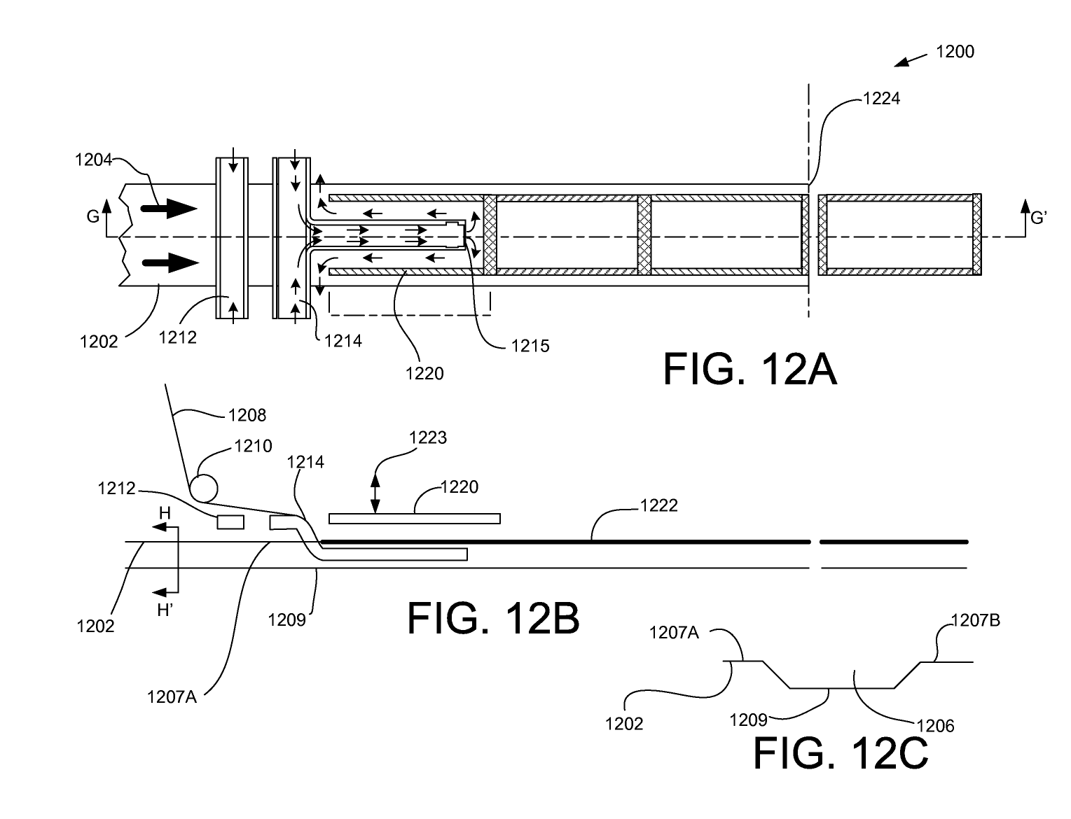

FIGS. 12A, 12B, and 12C are schematic diagrams of another system 1200 for forming pouches containing insulating gas. FIG. 12A is a schematic top view of the system 1200. FIG. 12B is a schematic side view of the system 1200 along section G-G′ in FIG. 12A. FIG. 12C is a schematic diagram of a transverse profile of the sheet of material along section H-H′ in FIG. 12B that includes a channel for receiving and containing insulating gas. A bottom sheet 1202 can be fed in a feed direction 1204 through the system. The bottom sheet 1202 can have a transverse profile that includes a channel 1206, as shown in FIG. 12C. The channel can be formed in a variety of ways including using techniques similar to those described above with respect to FIGS. 10 and 11. In other implementation, the channel can be formed though a progressive die set in which the material drawn over a die that progressively changes the profile of the material from that of a flat sheet to a profile that includes the channel 1206 between raised flanges 1207A, 1207B. Thus, the channel 1206 is formed between raised flanges 1207A, 1207B of the sheet 1202 and a bottom floor 1209 of the sheet 1202. A top sheet 1208 can be fed through the system at an average rate matched to the rate at which the bottom sheet 1202 is fed. The top sheet 1208 can be fed around a roller 1210 and brought into close proximity to the bottom sheet 1202.

When the top and bottom sheets are in close proximity to one another, a pre-purge gas can be introduced between the sheets via a duct, passageway, tube, or the like 1212. The pre-purge gas can include one or more gases having properties that improve the process of sealing the top sheet 1208 to the bottom sheet 1202 or that improve the performance of the final insulating-gas containing pouch product. For example, the pre-purge gas can include heated nitrogen having a very low water content, which may advantageously remove water vapor from the surface of the top and bottom sheets 1208, 1202 and from the gap between the sheets. In another example, the pre-purge gas can include a gas having a composition that is similar or identical to the insulating gas that is used in the pouch. Downstream from the pre-purge gas, the insulating gas can be introduced to the region between the top sheet 1208 and the bottom sheet 1202 for example, the insulating gas can be introduced through a duct 1214 that injects the gas into the area between the top sheet and the bottom sheet in a region of the system 1200 where the top sheet and the bottom sheets are sealed together. For example, the duct 1214 can have a T-shape or a J-shape, such that it can be supported from the side of the sheet with the gas flowing around the corner of the duct so that gas can be introduced from the side of the sheets, flow around a corner in the duct, and then the emitted from a nozzle 1215 at the end of a tube deep within the sealing region of the system. The nozzle may be considered to be the structure at and toward the end of the duct 1214 from which gas is emitted. The duct 1214 can be shaped such that gas is introduced in a combination of axial and transverse directions through a portion of the duct that is between the top sheet 1208 and the raised flanges 1207A, 1207B of the bottom sheet 1202. When the duct bends from its transverse direction and continues in the feed direction 1204, the duct also bends in a direction away from the top sheet 1208 and toward the floor 1209 of the channel 1206 of the bottom sheet 1202. Thus, the nozzle 1215 at the end of the duct from which insulating gas is emitted can be located within the channel between the raised flanges 1207A, 1207B and the bottom floor 1209.

As mentioned above, the insulating gas is emitted from the duct 1214 in a region of the system in which the top sheet 1208 is sealed to the bottom sheet 1202. In one implementation, the top sheet 1208 can be sealed to the bottom sheet 1202 with a “gang-forming” process in which the side edges and one end edge of a pouch are formed simultaneously in a first step, and then the second end edge is formed in a second step of the process. For example, as shown in FIG. 12A, a U-shaped press 1220 may be stamped on to the top sheet to pressure- and/or heat-seal the top sheet 1208 to the bottom sheet 1202 at the two side edges of a pouch and at one end edge, during a first step of the sealing process. The U-shaped press may have a “U” that lies in a plane, in which case the press 1220 is moved linearly (e.g., in direction 1223) to form the seal. The motion of the material 1202, 1208 in the feed direction 1204 may be momentarily halted during this sealing step. In another implementation, the “U” may be defined on a rotating member that rotates at a rate that the surface speed matches the speed at which the material is fed in the feed direction 1204, in which case the U-shaped seal is formed quickly as the member rotates but all edges of the U-shaped seal are not formed simultaneously. This first step of the sealing process may be performed while insulating gas is injected from the nozzle 1215 at the end of the duct 1214 into the channel between the top sheet 1208 and the bottom sheet 1202. Then, after the material has been fed downstream in the direction 1204 by a distance slightly less than the overall length of the U-shaped press 1220, the press may again contact and seal the films together to seal the top sheet to the bottom sheet completely containing and isolating the insulating gas, in a second step of the process.

In this manner, the base of the U of the press 1220 may be used to form both end edges of a pouch. Because insulating gas is continuously injected into the region between the top sheet 1208 and the bottom sheet 1202 as the material is fed downstream indirection 1204, when the second end edge is sealed by the U-shaped press 1220 the channel 1206 between the top sheet 1208 and the bottom sheet 1202 can be filled with a relatively high purity of insulating gas, and a relatively low amount of gas is lost from the pouches as they are formed. The thicker line 1222 in FIG. 12B is used to illustrate a sealed side edge between the top sheet 1208 and the bottom sheet 1202. Pouches that have been filled with insulating gas and totally sealed can be cut from the moving material by a cutting device 1224 by cutting the seal near the midline between two formed pouches, so that individual pouches filled with insulating gas are created.

In another implementation, the press 1220 can be H-shaped, where the horizontal bar of the “H” can be located toward the bottom of the “legs” of the “H.” With an H-shaped press, the press can be can be stamped to seal the top and bottom sheets when the horizontal bar of the “H” is slightly downstream from the end of the nozzle 1315, which may allow a larger gas pocket between the top and bottom sheets to exist just after the press is stamped than when a U-shaped press is used.

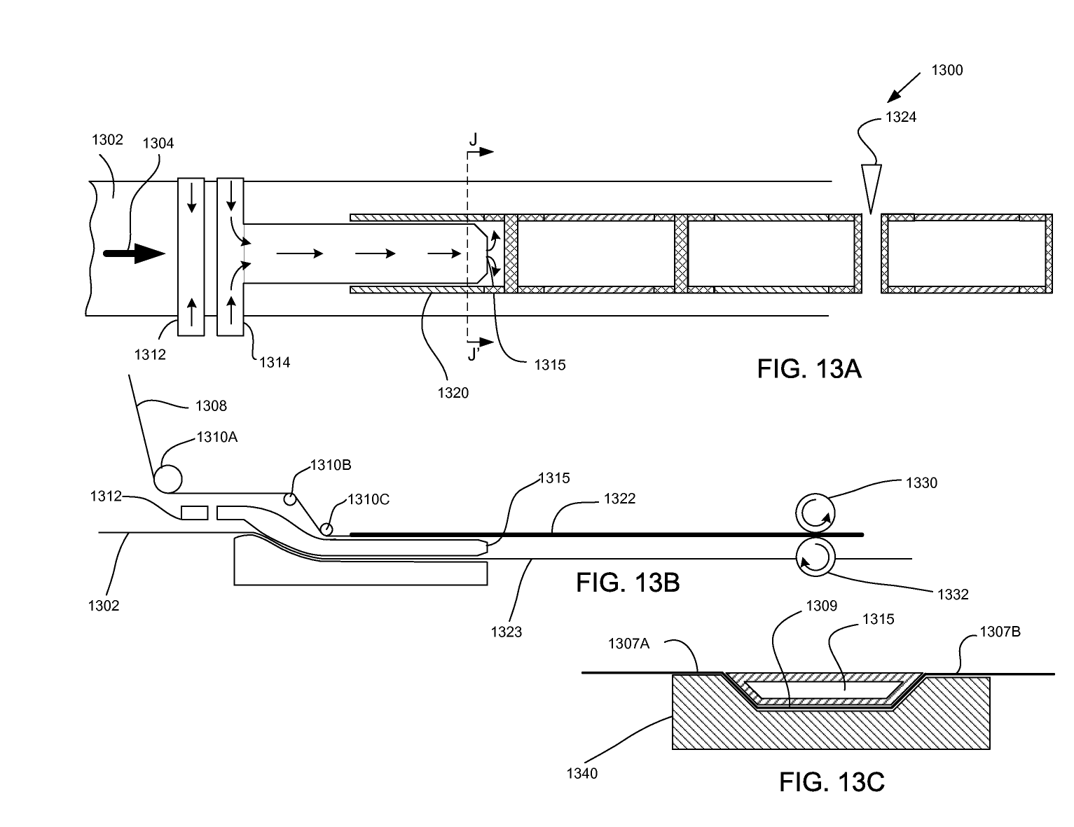

FIGS. 13A, 13B, and 13C are schematic diagrams of another system 1300 for forming pouches containing insulating gas. FIG. 13A is a schematic top view of the system 1300. FIG. 13B is a schematic side view of the system 1300. FIG. 13C is a schematic sectional view of the system 1300 through section J-J′ that is shown in FIGS. 13A and 13B. In the system 1300, a bottom sheet 1302 can have a transverse profile that includes a channel, as shown in FIG. 13C. The channel can be formed by using a duct 1314 through which insulating gas flows and/or a nozzle opening 1315 from which insulating gas is emitted between the bottom sheet 1302 and the top sheet 1308 as one part of a progressive die set through which the material of the bottom sheet 1302 is drawn, as explained in more detail below. The nozzle opening 1315 may be considered to be the structure at and toward the end of the duct 1314 from which gas is emitted. The nozzle opening itself may be tapered at the its downstream end to allow gas to flow out of the gas and into between the top and bottom sheets while the sheets are being sealed to each other without pressure from the emitted gas breaking or preventing the seal between the top and bottom sheets.

A bottom sheet 1302 can be fed in a feed direction 1304 through the system 1300 at an average rate matched to the rate at which the top sheet is fed. For example, the top sheet 1308 and bottom sheet 1302 can be pinched between one or more pairs of counter-rotating rollers 1330, 1332 that draw the sheet 1302 in the feed direction 1304. A top sheet 1308 can be fed around rollers 1310A, 1310B, 1310C and brought into close proximity to the bottom sheet 1202. The top sheet 1308 can be fed through the system 1300 at an average rate matched to the rate at which the bottom sheet 1302 is fed. For example, the top sheet 1308 can be pinched between the one or more pairs of counter-rotating rollers 1330, 1332 that drawn the sheet 1308 in the feed direction 1304.

As shown in FIG. 13C, the bottom sheet 1302 can have a transverse profile that includes a channel 1306 between raised flanges 1307A, 1307B, where the channel includes a bottom floor 1309. Also, as shown in FIG. 13C, the duct 1314, on one side, and a block 1340, on another side, can form two parts of a die set through which the bottom sheet 1302 is drawn, and the profiles of the duct 1314 and the block 1340 can define an opening through which the bottom sheet 1302 is drawn to form the channel in the bottom sheet 1302. The profile of the duct 1314 and the block 1340 define an opening that corresponds to the desired profile of the bottom sheet 1302 (i.e., including the channel in the bottom sheet) at one point along the feed direction 1304 of the sheet or over a finite distance of the feed direction. Although the opening between the duct 1314 and the block 1340 that corresponds to the desired transverse profile of the bottom sheet 1302 is shown to occur at section J-J′ at the end of the duct 1314, in other implementations the opening with such a shape may occur upstream of the end of the nozzle while the gap between the duct 1314 and the block 1340 may be substantially greater at the end of the nozzle. In still other implementations, the block 1340 may not extend all the way to the end of the nozzle 1315, and the opening between the duct 1314 and the block 1340 that corresponds to the desired transverse profile of the bottom sheet 1302 can occur upstream of the end of the nozzle (e.g., at one point along the feed direction or over a finite distance along the feed direction).

In addition, as shown in FIG. 13B, for example, at the portion of the block 1340 and the duct 1314 where the bottom sheet 1302 begins to pass between the block and the duct, the opening between the block 1340 and the duct 1314 can be greater than the thickness of the bottom sheet and greater the opening shown in FIG. 13C. Then, at points further downstream in the feed direction 1304, the opening between the block 1340 and the duct 1314 may gradually begin to change into the shape shown in FIG. 13C. This may allow the bottom sheet 1302 to be fed smoothly between the duct 1314 and the block as the sheet is drawn in the feed direction 1304. Thus, the desired channel in the bottom sheet 1302 can be formed by using the duct 1314 at the end of the duct as one part, or the entirety, of a progressive die set that is used to form the channel in the sheet.

When the top sheet 1308 and the bottom sheet 1302 are in close proximity to one another, a pre-purge gas can be introduced between the sheets via a duct, passageway, tube, or the like 1312. For example, the pre-purge gas can flow through a rectangular duct 1312 in a direction that is transverse to the feed direction 1304 and then can flow out of holes in bottom of the duct that face the top and/or bottom sheets or that face the downstream direction of the feed direction.

The pre-purge gas can include one or more gases having properties that improve the process of sealing the top sheet 1308 to the bottom sheet 1302 or that improve the performance of the final insulating-gas containing pouch product. For example, the pre-purge gas can include heated nitrogen having a very low water content, which may advantageously remove water vapor from the surface of the top and bottom sheets 1308, 1302 and from the gap between the sheets. In another example, the pre-purge gas can include a gas having a composition that is similar or identical to the insulating gas that is used in the pouch or be one of the components of the final desired gas mixture (e.g., Argon or Xenon). Using an inexpensive gas (e.g., Argon) allows optimizing performance of the completed part while reducing the cost of more expensive gas (e.g., Xenon).

Downstream from the duct 1312 that introduces the pre-purge gas, the insulating gas can be introduced to the region between the top sheet 1308 and the bottom sheet 1302. For example, the insulating gas can be introduced through the duct 1314 that injects the gas via nozzle opening 1315 into the area between the top sheet and the bottom sheet in a region of the system 1300 where the top sheet and the bottom sheets are sealed together. For example, the duct 1314 can have a generally “T” or “J” shape, such that it can be supported from the side of the sheet with the gas flowing around the corner of the duct so that gas can be introduced from the side of the sheets, so that gas can be introduced from the side of the sheets, flow around a corner in the duct, and then can be emitted from the end of the nozzle 1315 deep within the sealing region of the system. The duct 1314 and nozzle 1315 can be shaped such that gas is introduced substantially in the transverse direction through a portion of the duct that is between the top sheet 1308 and the raised flanges 1307A, 1307B of the bottom sheet 1302, and that when the duct bends and continues in the feed direction 1304, the duct also bends in a direction away from the top sheet 1308 and toward the floor 1309 of the channel of the bottom sheet 1302. Thus, the duct 1314 can form the channel in the bottom sheet, and the end of the nozzle from which insulating gas is emitted can be located within the channel between the raised flanges 1307A, 1307B and the bottom floor 1309.

As mentioned above, the insulating gas is emitted from the duct 1314 in a region of the system in which the top sheet 1308 is sealed to the bottom sheet 1302. In one implementation, the top sheet 1308 can be sealed to the bottom sheet 1302 with a “gang-forming” process in which the side edges and one end edge of a pouch are formed simultaneously in a first step, and then the second end edge is formed in a second step of the process. For example, as shown in FIG. 13A, an H-shaped press 1320 may be stamped on to the top sheet to pressure- and/or heat-seal the top sheet 1308 to the bottom sheet 1302 at the two side edges of a pouch and at one end edge, during a first step of the sealing process. The H-shaped press may have an “H” that lies in a plane, in which case the press 1320 is moved linearly to form the seal. The motion of the material 1302, 1308 in the feed direction 1304 may be momentarily halted during this sealing step. In another implementation, the “H” may be defined on a rotating member that rotates at a rate that the surface speed matches the speed at which the material is fed in the feed direction 1304, in which case the H-shaped seal is formed quickly as the member rotates but all edges of the H-shaped seal are not formed simultaneously. This first step of the sealing process may be performed while insulating gas is injected from the duct 1314 into the channel between the top sheet 1308 and the bottom sheet 1302. Then, after the material has been fed downstream in the direction 1304 by a distance slightly less than the overall length of the H-shaped press 1320, the press may again contact and seal the films together to seal the top sheet to the bottom sheet completely containing and isolating the insulating gas, in a second step of the process. The “top” legs of an H from a first pressing step may overlap with the “bottom” lets of an H of a second pressing process to entirely seal a pouch.

In another implementation, the press 1320 can be U-shaped, and the can be used to seal pouches in a manner similar to that described above with respect to FIGS. 12A, 12B, and 12C.

Because insulating gas is continuously injected into the region between the top sheet 1308 and the bottom sheet 1302 as the material is fed downstream indirection 1304, when two consecutive H-shaped pressing operations can create seal a pouch defined by a section of the top sheet and a section of the bottom sheet, where the pouch is filled with a relatively high purity of insulating gas, and a relatively low amount of gas is lost from the pouches as they are formed. The thicker line 1322 in FIG. 13B is used to illustrate a sealed side edges 1307A, 1307B between the top sheet 1308 and the bottom sheet 1302 as in FIG. 13C. The thin line 1323 in FIG. 13B is used to illustrate the floor of the bottom of the channel in the bottom sheet 1302 as in FIG. 13C. Pouches that have been filled with insulating gas and totally sealed can be cut from the moving material by a cutting device 1324, so that individual pouches filled with insulating gas are created. Surplus material of the top and bottom sheets around the sealed edges of the pouch also can be cut away by the cutting device 1324.

It will be appreciated that the above embodiments that have been described in particular detail are merely example or possible embodiments, and that there are many other combinations, additions, or alternatives that may be included.

What is claimed is:

1. A method of forming a pouch containing a gas, the method comprising:
drawing a first elongated sheet of gas-impermeable material from a supply of the material in a drawing direction, wherein the sheet of material has a transverse profile perpendicular to the drawing direction that includes a channel;
drawing a second elongated sheet of material, such that a first portion of the first sheet and a first portion of the second sheet are substantially parallel to each other;
injecting the gas between the first portion of the first sheet and the first portion of the second sheet, wherein the gas is injected between side edges of the first portions of the first and second sheets;
sealing first and second lengths of the first and second sheets to each other, wherein the first and second lengths are substantially parallel to the drawing direction, to form first and second side edges of the pouch; and
sealing third and fourth lengths of the first and second sheets to each other, wherein the third and fourth lengths are substantially perpendicular to the drawing direction, to form first and second end edges of the pouch.

2. The method of claim 1, wherein the first and second sheets each include a metal layer.

3. The method of claim 1, wherein injecting the gas includes providing the gas to a location between the first portion of the first sheet and the first portion of the second sheet and between the first and second lengths of the sheets through a duct and a nozzle opening located between the first portion of the first sheet and the first portion of the second sheet and between the first and second lengths of the sheets.

4. The method of claim 3, wherein a transverse profile of the duct is shaped to from the channel in the first sheet as the first sheet is drawn past the duct in the drawing direction.

5. The method of claim 3, wherein the first sheet is drawn in the drawing direction through an opening between the duct and a block that together form a progressive die set, wherein the first sheet does not include the channel before it is drawn into the opening and wherein drawing the sheet through the opening forms the channel in the first sheet.

6. The method of claim 1, wherein the gas is injected as the first sheet and the second sheet are drawn in the drawing direction.

7. The method of claim 1, wherein sealing the first, second, third, and fourth lengths of the first and second sheets to each other includes:
sealing, in a first sealing operation, the first, second, and third lengths of the first and second sheets to each other; and then
sealing, in a second sealing operation, the fourth lengths of the first and second sheets to each other.

8. The method of claim 7,
wherein the first sealing operation includes forming the first side edge, the second side edge, and the first end edge of a first pouch,
wherein the second sealing operation includes forming the second end edge of the first pouch and forming a first side edge, a second side edge, and a first end edge of a second pouch, and further comprising:
sealing, in a third sealing operation, fifth lengths of the first and second sheets to each other to form a second end edge of the second pouch.

9. The method of claim 8, wherein the first sealing operation includes forming substantially simultaneously the first side edge, the second side edge, and the first end edge of a first pouch.

10. The method of claim 9,
wherein the first sealing operation includes forming the first side edge, the second side edge, and the first end edge of a first pouch by pressing the first, second, and third lengths of the first and second sheets together with a linearly-translated tool, and
wherein second sealing operation includes forming the second edge of the first pouch by pressing the fourth lengths of the first and second sheets together with the tool.

11. The method of claim 8, wherein the first sealing operation includes, in a first continuous sealing operation, sealing the third length of the first and second sheets to each other, and then progressively sealing the first and second lengths of the first and second sheets to each other, starting from ends of the first and second lengths that are proximate to the third length, progressing along the first and second lengths, and ending with ends of the first and second lengths that are proximate to the fourth length.

12. The method of claim 11,
wherein the first sealing operation includes forming the first side edge, the second side edge, and the first end edge of a first pouch by pressing the first, second, and third lengths of the first and second sheets together with a rotating tool,
wherein second sealing operation includes forming the second edge of the first pouch by pressing the fourth lengths of the first and second sheets together with the tool.

13. The method of claim 8, further comprising:
cutting the first pouch away from the second pouch.

14. The method of claim 1, wherein sealing the first, second, third, and fourth lengths of the first and second sheets to each other includes applying heat to the lengths.

15. The method of claim 1, wherein sealing the first, second, third, and fourth lengths of the first and second sheets to each other includes applying pressure to the lengths.

16. The method of claim 1, wherein the gas is an insulating gas that has a lower heat conductivity than air.

17. The method of claim 16, wherein the gas includes xenon.

18. The method of claim 1, further comprising injecting the gas at a rate such that a pressure of the gas in the pouch after the pouch has been sealed is greater than atmospheric pressure.

19. The method of claim 1, further comprising:
drawing the first sheet in the drawing direction through an opening in a progressive die set, wherein the first sheet does not include the channel before it is drawn into the opening and wherein drawing the sheet through the opening forms the channel in the first sheet.

20. The method of claim 1, further comprising:
rolling the first sheet between a pair of parallel, counter-rotating, non-cylindrical rollers, wherein the rollers have radii as a function of their lengths that define the channel in the first sheet when the sheet is rolled between the rollers.

21. A device comprising:
a heat-dissipating component;
one or more heat-generating components, at least one heat-generating component located in proximity to an inner surface of the heat-dissipating component, wherein a gap exists between the at least one heat-generating component and the inner surface of the heat-dissipating component; and
an thermal insulator, located in the gap, the insulator including a structure enclosing an insulating gas, the insulating gas having a thermal conductivity lower than air,
wherein the structure enclosing the insulating gas includes a material having a thermal conductivity greater than air and has transverse dimension at least 1.3 times greater than a transverse dimension of the heat-generating component.

22. The device of claim 21, wherein the structure includes a material having a thermal conductivity greater than 15 Watts per meter-Kelvin.

23. The device of claim 21, wherein the structure includes a material having a thermal conductivity greater than 150 Watts per meter-Kelvin.

24. The device of claim 21, wherein the insulating gas has a thermal conductivity that is lower than 50% of the thermal conductivity of air.

25. The device of claim 21, wherein the structure enclosing the insulating gas is in contact with the heat-generating component and is in contact with the heat-dissipating component.

26. The device of claim 21, wherein the heat-dissipating component includes a metal.

27. The device of claim 21, wherein the metal includes aluminum.

28. The device of claim 21, wherein the thermal conductivity and dimensions of the structure are selected such when the heat-generating component is generating heat, the heat from the heat-generating component is conducted through the structure to the heat-dissipating component and raises the temperature of the heat-dissipating component by a threshold amount, compared to when the heat-generating component is not generating heat, over an area that is greater than an area over which the temperature of the heat-dissipating component would be raised by the threshold amount in the absence of the insulator, while maintain a peak temperature of the heat-dissipating component that is lower than a peak temperature of the heat-dissipating component that would exist in the absence of the insulator.

29. The device of claim 21, wherein dimensions and materials of the insulator are selected such that a heat transfer rate between the heat-generating component and the heat-dissipating component is greater than in the presence of the insulator than in the absence of the insulator.

30. The device of claim 21, wherein dimensions and materials of the insulator are selected such that a heat transfer rate between the heat-generating component and the heat-dissipating component is less than in the presence of the insulator than in the absence of the insulator.
